(19) United States
(12) Patent Application Publication
(10) Pub. No.: US 2008/0013671 A1
(43) Pub. Date: Jan. 17, 2008

(54) Frequency Division by Odd Integers

(75) Inventors: Remco Cornelis Herman Van De Beek, Eindhoven (NL); Dominicus Martinus Willhelmus Leenaerts, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/718,801

(22) PCT Filed: Nov. 9, 2005
(86) PCT No.: PCT/IB05/53679

§ 371 Date: May 8, 2007

(30) Foreign Application Priority Data
Nov. 15, 2004 (EP) 04105753.0

(51) Int. Cl. H03K 23/48

(52) U.S. Cl. 377/118

(57) ABSTRACT

The invention relates to a method and device for providing at least a first output signal (O Q) having a frequency that is obtained through dividing a clock signal (CL1) frequency by an odd integer. A digital value is shifted into a set of latches based on the clock signal (CL1) and kept there a predetermined number of half clock cycles. The value is shifted into a following latch delayed with half a clock cycle of the clock signal compared with a previous latch. Then a first (Q1) and a second (Q6) intermediate signal, each provided through information stored in a latch, are interpolated for forming said first output signal (O Q). Because of this it is possible to provide an output signal having edges displaced from clock signal edges, thus allowing a higher resolution than the original clock signal has and in particular, enabling quadrature outputs from a standard odd-integer frequency divider.

The present invention generally relates to the field of frequency division and more particularly to a method and device for providing at least one output signal that is obtained through dividing a clock signal by an odd integer.

In the field of radio communication it is often of interest to use different frequencies for communication within the same network. An example of such a network is a Wireless LAN network.

An important function in radio communication is frequency translation. To do this, it is often of interest to generate signals using quadrature coding, where a signal is provided in a certain phase and a certain frequency and another related signal is provided in the same frequency but phase shifted from the first signal by a certain phase, like with say 90 degrees. When providing these types of signals at different frequencies it is common to use one clock signal source in the form of an oscillator for providing the different frequencies. The frequency of the clock signal is then divided down in order for it to be used for an alternative frequency. Normally, such divided down frequencies are then provided by a prescaler following the oscillator. After the prescaler there can then be provided another circuit that provides the in-phase and quadrature signals.

It would furthermore be advantageous to provide one circuit or device that provides both the dividing of the frequency as well as two such in-phase and quadrature signals. Such a solution is of interest since then the number of components and thus the cost of the device in which frequency division is to be used is kept low.

This is however not a simple task to do once the frequency is to be divided by an odd integer, because then the main clock signal used does not have a resolution allowing the provision of a phase shift of ninety degrees. This might be necessary because the system where the different frequencies are used stipulates the use of frequencies that can only be obtained by a division with an odd integer.

US 2002/0171458 describes a frequency divider that divides an input frequency with an odd integer and provides an output signal having a 50% duty cycle. This document does describe how one signal is generated, but does not provide a phase shifted signal in relation to this signal.

There might furthermore exist other situations where it is of interest to generate signals that need a higher clock signal resolution than what can be provided from a divided down signal.

There is thus a need for an improved frequency division scheme and in particular one that enables the division of a clock signal with an odd integer while at the same time providing a finer resolution than the clock signal can provide.

It is thus an object of the present invention to provide an improved frequency division scheme.

According to a first aspect of the present invention, this object is achieved by a method of providing at least a first output signal having a frequency that is obtained through dividing a clock signal frequency by an odd integer comprising the steps of:

shifting a digital value into a set of latches based on the clock signal and keeping said value in each latch a predetermined number of half clock cycles, where said value is shifted into a following latch delayed with half a clock cycle of the clock signal compared with a previous latch, and

interpolating a first and a second intermediate signal, each provided through information stored in a latch, for forming said first output signal.

According to a second aspect of the present invention, this object is also achieved by a device for providing at least a first output signal having a frequency that is obtained through dividing a clock signal frequency by an odd integer comprising:

a set of latches, into which a digital value is shifted based on the clock signal and each latch being arranged to keep said value a predetermined number of half clock cycles, where said value is shifted into a following latch delayed with half a clock cycle of the clock signal compared with a previous latch, and

an interpolating unit arranged to interpolate a first and a second intermediate signal, each provided through information stored in a latch, for forming said first output signal.

The present invention has the advantage of allowing the use of a finer resolution than the clock signal provides when a frequency is to be divided by an odd integer. This allows the provision of such signals as quadrature signals in relation to in-phase signals for such divided down frequencies. Because of this it is furthermore possible to let the same device provide different signals that are to be phase shifted in relation to each other, which makes the invention furthermore save the number of components used. The invention is furthermore easy to implement with simple components and circuits.

Claims 2 and 11 are directed towards using the first and (N+1)-th latch of the set for providing the first and second intermediate signals, where N is the integer by which the clock signal frequency is divided. This has the advantage of allowing the first output signal to be provided as a quadrature signal for a corresponding in-phase signal.

According to claim 3, one intermediate signal is provided as the inverse of the information stored in the corresponding latch. This feature allows the provision of a duty cycle of fifty percent if the intermediate signals do not have this.

Claims 4 and 12 are directed towards combining the signal edges of the first and second intermediate signals. This feature has the advantage of providing a signal that has a finer resolution than the clock signal allows.

According to claim 5, finitely steep partly overlapping edges of the first and second intermediate signals are combined. This feature has the advantage of providing a simple way of interpolating the intermediate signals using standard components.

Claims 6 and 13 are directed towards processing a third and fourth intermediate signal for providing a second output signal. This feature has the advantage of allowing the first output signal to be provided as a signal that is shifted in phase from the second output signal with a resolution the clock signal cannot handle.

According to claims 7 and 14, the signal edges of the third and fourth intermediate signals are combined for providing the second output signal. This feature has the advantage of providing a fifty percent duty cycle out of signals that do not have this duty cycle.

According to an optional feature of the present invention, the third and fourth intermediate signals are provided by latches of the shift register connected to each other.

According to claims 8 and 15, the ((N+1)/2)-th and ((N+1)/2+1)-th latch in the set are used for providing the second and third intermediate signals, where N is the integer by which the clock signal frequency is divided. This feature has the advantage of allowing the first output signal to be provided with a phase shift of ninety degrees in relation to the second output signal.

According to an optional feature of the present invention the digital value is shifted in cyclically in the set of latches and the number of a latch corresponds to the order in which it receives the digital value in a shifting cycle.

According to yet an optional feature of the present invention, there are N+1 latches in the set, According to yet an optional feature of the present invention output signals generated have a duty cycle of fifty percent.

The general idea behind the invention is to interpolate first and second intermediate signals that have been obtained from two latches in a set of latches provided for dividing down a clock frequency. Because of this it is possible to provide an output signal that has its edges displaced from clock signal edges and thus allows a higher resolution than the original clock signal has.

These and other aspects of the invention will be apparent from and elucidated with reference to the embodiments described hereinafter.

The present invention will now be explained in more detail in relation to the enclosed drawings, where

FIG. 1 shows a block schematic of frequency dividing device according to a first embodiment of the present invention that divides a clock frequency with an integer of five,

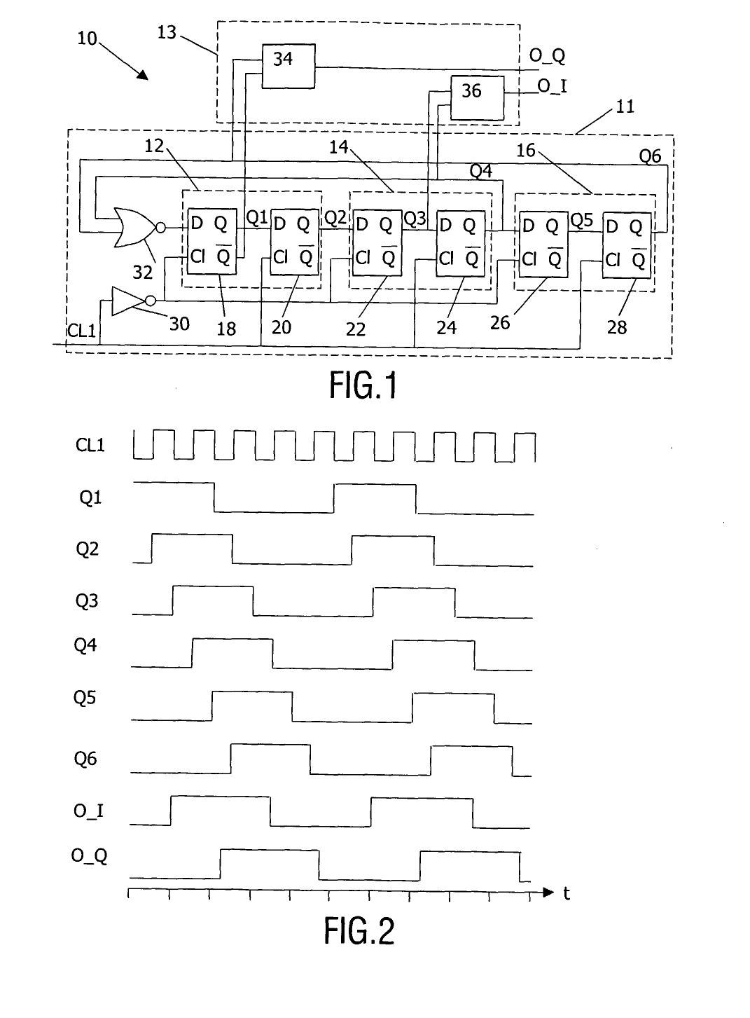

FIG. 2 schematically shows signals provided and generated in the frequency dividing device of FIG. 1,

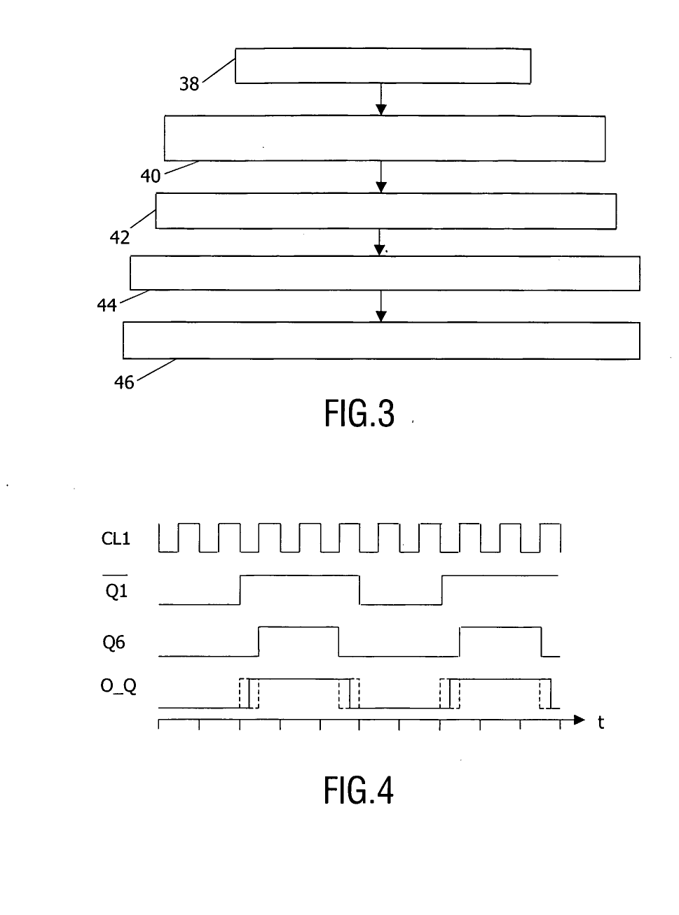

FIG. 3 shows a flow chart of a method of providing output signals according to the present invention performed in the frequency dividing device,

FIG. 4 schematically shows some of the signals from FIG. 2 in more detail in order to explain the generating of a first output signal according to the present invention,

FIG. 5 shows a block schematic of an example of an interpolating unit provided in the frequency dividing device of FIG. 1,

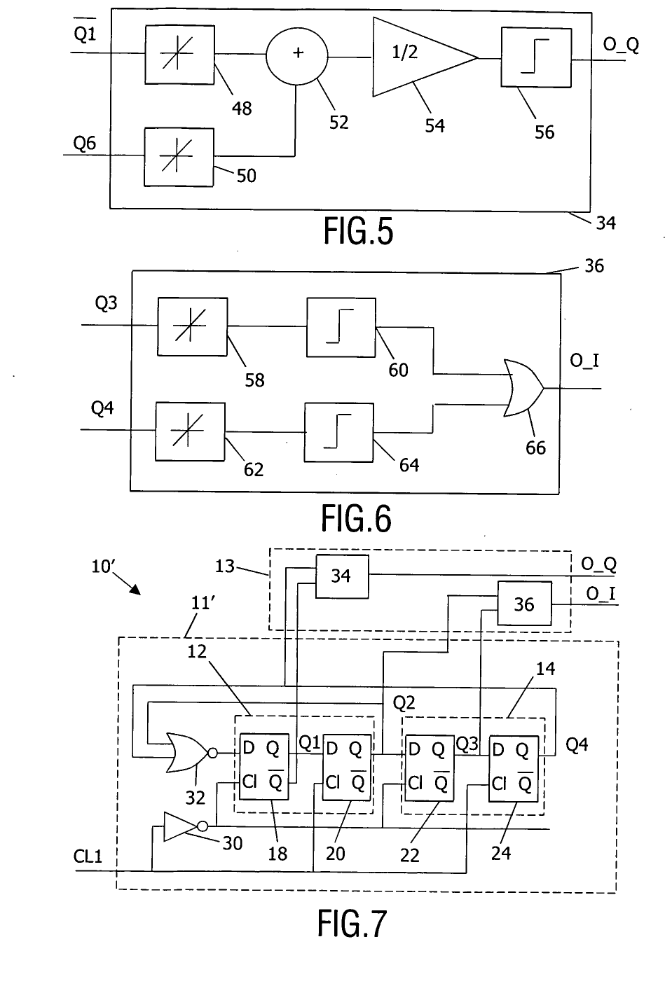

FIG. 6 shows a block schematic of an example of a signal edge copying unit provided in the frequency dividing device of FIG. 1,

FIG. 7 shows a block schematic of a frequency dividing device according to a second embodiment of the present invention that divides a clock frequency with an integer of three, and

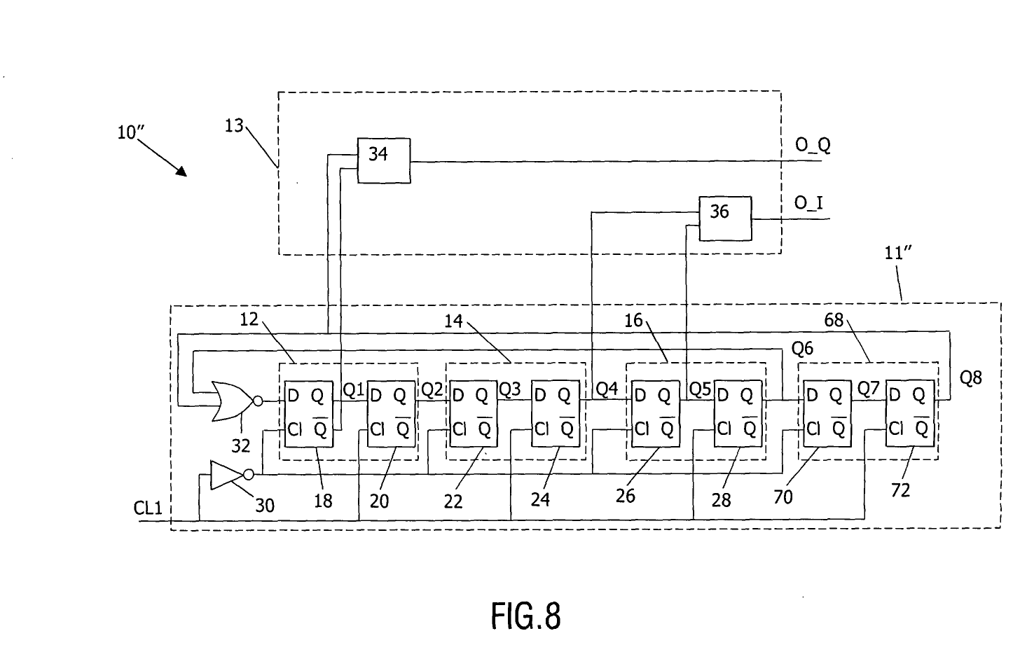

FIG. 8 shows a block schematic of a frequency dividing device according to a third embodiment of the present invention that divides a clock frequency with an integer of seven.

The present invention is directed towards providing frequency division with an odd integer. Such frequency division might be of interest when providing communication frequencies for different communication bands, like for instance different wireless LAN network frequencies, where for instance the frequency bands 17 GHz and 5 GHz are provided. According to the present invention the same device is used for providing a divided down in-phase signal and quadrature signal and thus there is no need for extra devices for providing for instance the quadrature signal.

FIG. 1 shows a block schematic of a frequency dividing device 10 according to a first embodiment of the present invention. The frequency dividing device 10 includes a core frequency dividing unit 11 (indicated by a dashed box) and a post processing unit 13 (indicated by a dashed box). The core frequency dividing unit 11 comprises a number of D-flip flops 12, 14, 16 that are connected in cascade. Each D-flip flop comprises two D-latches. All the latches make up a set of latches. A first D-flip flop 12 in the set thus comprises a first D-latch 18 connected to a second D-latch 20, while a second D-flip flop 14 comprises a third D-latch 22 and a fourth D-latch 24, while a third D-flip flop 16 comprises a fifth D-latch 26 and a sixth D-latch 28. Here the latches can be seen as organized as a shift register, through which a digital value can be shifted. Each D-latch comprises a signal input D, a clock signal input C1, a first signal output Q and a second inverse signal output. The signal input D of the first latch 18 is connected to the output of a NOR gate 32, while the first output Q of the first latch 18 is connected to the signal input D of the second latch 20 and provides an output signal Q1 to this input. The first output Q of the second latch 20 is connected to the signal input D of the third latch 22 and provides a signal Q2 to this input, while the first output Q of the third latch 22 is connected to the signal input D of the fourth latch 24 and provides a signal Q3 to this input. The first output Q of the fourth latch 24 is connected to the signal input D of the fifth latch 26 and provides a signal Q4 to this input. The first output Q of the fifth latch 26 is connected to the signal input D of the sixth latch 28 and provides a signal Q5 to this input. The first output Q of the sixth latch 28 is connected to a first input of the NOR gate 32 and provides a signal Q6 to this input, while the first output Q of the fourth latch 24 is connected to a second input of the NOR gate 32. The frequency dividing device 10 furthermore receives a clock signal CL1 from an oscillator (not shown), which is directly supplied to the clock inputs C1 of the second, fourth and sixth latches 20, 24, 28. The clock signal CL1 is also supplied to an inverter 30, which in turn is connected to the clock inputs C1 of the first, third and fifth latches 18, 22, 26. The post processing unit 13 includes an interpolating unit 34 which is connected to the second output of the first latch 18 for receiving the inverse of the signal Q1 and to the first output Q of the sixth latch 28 for receiving the signal Q6. The interpolating unit 34 then provides a first output signal O_Q based on these input signals. The post processing unit 13 also includes a signal edge copying unit 36, which is connected to the first outputs Q of the third and fourth latches 22, 24 for receiving the signals Q3 and Q4 and processing these to provide a second output signal O_I.

FIG. 2 shows the clock signal CL1 provided to the set of registers in FIG. 1 together with the signals Q1, Q2, Q3, Q4, Q5 and Q6 as well as the output signals O_I and O_U generated by the interpolating and signal edge copying units. FIG. 3 shows a block schematic of a method according to the present invention.

The working of the device in FIG. 1 will now be described with reference being made also to the signals shown in FIG. 2 and to the flow chart shown in FIG. 3. The frequency dividing device 10 receives a clock signal CL1 that is used in known fashion to clock the D-latches 18, 20, 22, 24, 26, 28, where a D-latch takes on and provides an input value received on a signal input D as output value Q as long as its C1 input is low; the D-latch is transparent from D to Q as long as C1 is high. Thus here the second, fourth and sixth latches 20, 24, 28 take on such an input value on a rising edge of the clock signal CL1 and the first, third and fifth latches 18, 22, 26 take on an input value on a falling edge of the clock signal CL1 because of the inverter 30. Each of the latches 18, 20, 22, 24, 26 and 28 keeps the value a predetermined number of half clock cycles and the value is shifted into a following latch delayed with half a clock cycle compared with a previous latch. The core frequency dividing unit 11 is thus a state-machine that cycles through five states, thus performing division, which is well known within the art. However the duty cycle of these signals Q are not fifty percent, which can be seen in that each of the signals Q1-Q6 go high for two full clock cycles and low for three full clock cycles. In the following the inverse of the signal Q1 will be termed a first intermediate signal, the signal Q6 a second intermediate signal, the signal Q3 a third intermediate signal and the signal Q4 a fourth intermediate signal. The third and fourth intermediate signals Q3 and Q4 are then provided to the signal edge copying unit 36 from the latches in the middle of the shift register, step 40, i.e. the third and fourth latches 22 and 24. The signal edge copying unit 36 goes on and combines these signals in order to provide the second output signal O_I, step 42. It does this by copying the rising edge of the signal Q3 and the following falling edge of the signal Q4 and providing a high level in-between. The level provided in-between is the level that both the third and fourth intermediate signal have for the majority of the interval defined by said rising and falling edges. In this way there is provided a signal that is an in-phase signal having a duty cycle of fifty percent and that has been divided down by five in relation to the clock signal CL 1. The first intermediate signal is also obtained as well as the second intermediate signal Q6 from the first 18 and last 26 latches in the set, where these signals are provided to the interpolating unit 34, step 44. The interpolating unit 34 then interpolates these signals in order to obtain the first output signal O_Q shown in the bottom of FIG. 2, step 46. In this way a quadrature signal associated with the in-phase signal is generated that is shifted in phase in relation to the in-phase signal with ninety degrees, which is also evident from the two last signals of FIG. 2.

The different method steps of FIG. 3 are outlined in table 1 below.

TABLE 1

| | |
|---|---|
| 38 | SHIFT VALUE INTO LATCHES |
| 40 | OBTAIN Q3 AND Q4 FROM MIDDLE LATCHES |
| 42 | COMBINE Q3 AND Q4 FOR PROVIDING O_I SIGNAL |
| 44 | OBTAIN AND Q6 FROM FIRST AND LAST LATCHES |
| 46 | INTERPOLATE AND Q6 FOR OBTAINING O_Q SIGNAL |

How the interpolation is performed will now be described in more detail by looking more closely at FIG. 4, which shows the clock signal CL1 together with the signals Q1 and Q6 as well as the output signal O_Q, which is generated based on the signals Q1 and Q6.

The interpolating unit takes the first intermediate signal ( Q̅1̅) and interpolates it and the second intermediate signal Q6. It thus obtains the rising edges of the first intermediate signal and the second intermediate signal and interpolates these. The result is that the first output signal O_Q signal receives a rising edge in the middle between the rising edge of the first intermediate signal ( Q̅1̅) (shown with a dashed line) and the second intermediate signal Q6 (shown with a dashed line). In the same way the falling edges of the first and second intermediate signals are treated, i.e. by interpolation. Also here a falling edge of the resulting signal is provided between the falling edges of the first intermediate signal and the second intermediate signal. In-between these rising and falling edges the output signal receives the high level that is evident in both the first and second intermediate signals. As can also be seen in FIG. 4, the result is that the signal edges of the first output signal are provided at a point in time that is shifted a quarter of a clock cycle from the edges of the clock signal CL1. This allows a phase shift of ninety degrees for such a divided down frequency. In this way it is thus ensured that a fifty percent duty cycle is provided together with a ninety degree phase shift in relation to the second in-phase output signal. The interpolation process thus increases the time resolution of the output signal.

One way of implementing the interpolating unit is shown in FIG. 5. The first intermediate signal ( Q̅1̅) is here provided to a first rate limiter 48, while the second intermediate signal Q6 is provided to a second rate limiter 50. From these rate limiters 48, 50 the signals are provided to a mean value calculating unit, which determines the mean value of the rate limited signals. The mean value calculating unit here comprises an adding unit 52 which adds the two signals together and a multiplying unit 54 which multiplies the obtained sum with ½, i.e. performs a division. The thus calculated mean value is then provided to a first slicer or amplifier 56, which makes sure that the divided signal receives a high level if a certain signal level is exceed and otherwise a low level, which signal level is preferably half the maximum normal output signal level. The rate limiters 48, 50 ensure that the signals do not change from high to low and low to high levels too fast, in order to obtain finitely steep, partly overlapping signal edges of the first and second intermediate signals. These can then be combined using interpolation, where the actual interpolation is performed by taking the mean of the two signals. With this realization it is ensured that the high signal level is provided in a quarter of a clock cycle and ended in a quarter of a clock cycle, when the signals are added to each other. It should however be realized that the implementation in FIG. 5 is just one out of many possible implementations. In fact, the representation in FIG. 5 is to be interpreted as conceptual. There are thus many other ways in which this interpolation might be performed. It is for instance equally as well possible that the first and second intermediate signals are provided as currents. In this case it is possible to implement the interpolation by interconnecting the current generating nodes. The gain of ½ is obtained by a suitable choice of a resistor value for a resistor that converts the current to a voltage.

One way of implementing the signal edge copying unit 36 is shown in FIG. 6. Here there is provided a third rate limiter 58 that receives the third intermediate signal Q3 and passes it on to a second slicer 60 and a fourth rate limiter 62 which receives the fourth intermediate signal Q4 and passes it on to a third slicer 64. The rate limiters and slicers work in the same way as was described above and are added to maintain a phase difference of 90 degrees between the output signals O_I and O_Q. The signals are then provided to an OR gate 66 which performs a logical OR operation on the two signals and thus provides the second output signal O_I. Here it should be realized that a number of alternative ways of generating the output signal O_I can be provided. What is necessary though is that the unit will copy the rising edge of the third signal and the falling edge of the fourth signal and provide a high level in-between these in order to provide the output signal.

It should here be noted that it might be possible to provide the interpolating unit without explicit rate limiters and perhaps also without an explicit slicer or amplifier; the rate limitation may for example be a parasitic property of the latch circuit due to output capacitance. If there is no rate limiter in the interpolating unit 34 there is also no need for rate limiters in the signal edge copying unit 36. This latter unit might then not include slicers either.

It should be realized that the present invention is not limited to a division by five. FIG. 7 shows an example of such a device 10′. The core frequency dividing unit 11′ is here provided for division with an integer that is three. The difference from the device in FIG. 1 is here that the fifth and sixth latches are omitted. Consequently the fourth signal Q4 and the second signal Q2 are provided to the OR gate 32. The interpolating unit 34 receives the signal Q4 and, while the signal edge copying unit receives the signals Q2 and Q3. The operation of the units will however be similar to what has been described above.

It is furthermore possible to also provide division by a higher odd multiple, and a division by a multiple of seven is indicated by the device 10″ in FIG. 8. The device 10″ in FIG. 8 differs from the device in FIG. 1 in that the core frequency dividing unit 11″ further comprises a fourth D-flip flop 68. The fourth D-flip flop 68 is connected in cascade with the third D-flip flop 16 and receiving the same type of clocking signals as the third D-flip flop 16. The fourth D-flip flop 68 here includes a seventh D-latch 70 connected to an eighth D-latch 72, where the signal input D of the seventh latch 70 receives the signal Q6, provides a signal Q7 on its first output Q, which in turn is connected to the signal input D of the eighth latch 72 that provides a signal Q8 on its first output Q. Here the NOR gate 32 receives the signals Q6 and Q8, while the interpolating unit 36 receives the signals and Q8, i.e. the signals from the first and last latches of the set, and the signal edge copying unit 36 receives the signals Q4 and Q5, i.e. the signals from the latches in the middle of the set. In all other respects the device in FIG. 8 functions in the same way as the device in FIG. 1.

The principle for providing registers or latches when a division with an odd integer N is desired, will generally be provided using a set of N+1 latches or (N+1)/2 flip flops connected in cascade. These latches provide a high signal level for (N−1)/2 clock cycles and a low signal level for (N+1)/2 clock cycles or vice versa depending on the placement of the inverter. Here the interpolating unit receives intermediate signals from the first and the (N+1)-th latches and the signal edge copying unit receives intermediate signals from the ((N+1)/2)-th and ((N+1)/2+1)-th latches. Here the numbering of the latches corresponds to the order in which they receive a value being shifted through the latches in a shifting cycle.

Above it was described that in-phase signals were provided together with quadrature signals, where the signal edge copying unit provided the in-phase signal and the interpolating unit the quadrature signal. It is equally as well possible to let the signal edge copying unit provide the quadrature signal and the interpolating unit provide the in-phase signal. The teachings of the present invention can furthermore be used for the generation of only one output signal, which single output signal is then provided by the interpolating unit. In this case there would be no need for the signal edge copying unit. This sole output signal can then be seen as an in-phase signal. The interpolating unit is then merely used to obtain a 50% duty cycle signal.

The present invention has a number of advantages. It allows the use of a finer resolution than the clock signal provides when a frequency is to be divided by an odd integer. This allows the provision of such signals as quadrature signals in relation to in-phase signals for such divided down frequencies. Because of this it is furthermore possible to let the same device provide different signals that are to be phase shifted in relation to each other by less than one hundred and eighty degrees, which makes the invention save the number of components used. The invention is furthermore easy to implement. It can be implemented by just adding an interpolating unit and possibly also a signal edge copying unit to a known and needed core frequency dividing unit, which additional unit or units are easy to implement by a limited number of additional components.

There are several variations that can be made to the present invention apart from the variations already described. It is for instance possible to provide other shifts than ninety degrees below one hundred and eighty degrees, like for instance by a shift of forty five degrees or a shift of one hundred and thirty-five degrees. If the interpolating unit applies a weighted average of the rate limited output signals rather than taking the mean of the two, other phase shifts can be achieved, meaning that an improvement in timing resolution of a factor of two is not the limit. It should also be noted that the present invention is not limited to using the inverted output signal of the first latch in the interpolation. It is for instance possible that instead it is the output signal of the (N+1)-th latch that is inverted, while the output signal of the first latch is not. It should also be noted that the NOR gate in the core frequency dividing unit can also be replaced by one or more different gates, like for instance a NAND gate. The essence is that a divider based on a shift register is used, where the signal edge copying unit and the interpolating unit are employed to generate the 50% duty cycle and in-phase and quadrature signals.

The invention can be implemented in any suitable form including hardware, software, firmware or combinations of these. However, preferably, the invention is implemented as hardware. The elements and components of an embodiment of the invention may be physically, functionally and logically implemented in any suitable way. Indeed the functionality may be implemented in a single unit, in a plurality of units or may be physically and functionally distributed between different units and processors.

Although the present invention has been described in connection with a specific embodiment, it is not intended to be limited to the specific form set forth herein. Rather, the scope of the present invention is limited only by the accompanying claims. In the claims, the term comprising does not exclude the presence of other elements or steps. Furthermore, although individually listed, a plurality of means, elements or method steps may be implemented by e.g. a single unit or processor. Additionally although individual features may be included in different claims, these may possibly be advantageously combined and the inclusion in different claims does not imply that a combination of features is not feasible and/or advantageous. In addition singular references do not exclude a plurality. Thus references to “a”, “an”, “first”, “second” etc. do not preclude a plurality. Reference signs in the claims are provided merely as a clarifying example and shall not be construed as limiting the scope of the claims in any way.

1. Method of providing at least a first output signal (O_Q) having a frequency that is obtained through dividing a clock signal (CL1) frequency by an odd integer comprising the steps of:
shifting a digital value into a set of latches (18, 20, 22, 24, 26, 28; 18, 20, 22, 24; 18, 20, 22, 24, 26, 28, 70, 72) based on the clock signal and keeping said value in each latch a predetermined number of half clock cycles, where said value is shifted into a following latch delayed with half a clock cycle of the clock signal compared with a previous latch, (step 38), and
interpolating a first ( Q̅1̅) and a second (Q6; Q4; Q8) intermediate signal, each provided through information stored in a latch (18, 28; 18, 24; 18, 72), (step 46), for forming said first output signal.

2. Method according to claim 1, wherein the first output signal is formed from a first intermediate signal provided from the first latch of the set and from a second intermediate signal provided from the (N+1)-th latch of the set, where N is the integer by which the clock signal frequency is divided.

3. Method according to claim 1, wherein one intermediate signal of the signals used for interpolation comprises the inverse of the information stored in the corresponding latch of the set and the other intermediate signal comprises the same information as the information stored in the corresponding latch of the set.

4. Method according to claim 1, wherein the step of interpolating comprises combining the signal edges of the first and second intermediate signals, such that the first output signal has edges at points in time that are shifted from the edges of the clock signal.

5. Method according to claim 4, wherein the step of interpolating comprises combining finitely steep, partly overlapping signal edges of the first and second intermediate signals.

6. Method according to claim 1, further comprising the step of processing a third (Q3; Q2; Q4) and fourth (Q4; Q3; Q5) intermediate signal provided through two other latches (22, 24; 20, 22; 24, 26), (step 42), in order to provide a second output signal (O_I) having the same frequency as the first output signal but with a different phase.

7. Method according to claim 6, wherein the processing comprises obtaining an edge of one type of the third intermediate signal and a following edge of an opposite type of the fourth intermediate signal and providing a level in-between that both the third and fourth intermediate signal have for the majority of the interval defined by said edges for the second output signal.

8. Method according to claim 6, wherein the third and fourth intermediate signals are obtained from the ((N+1)/2)-th and ((N+1)/2+1)-th latch in the set, where N is the integer by which the clock signal frequency is divided.

9. Method according to claim 6, wherein the second output signal is an in-phase signal and the first output signal is a quadrature signal or vice-versa.

10. Device (10; 10′; 10″) for providing at least a first output signal (O_Q) having a frequency that is obtained through dividing a clock signal (CL1) frequency by an odd integer comprising:
a set of latches (18, 20, 22, 24, 26, 28; 18, 20, 22, 24; 18, 20, 22, 24, 26, 28, 70, 72), into which a digital value is shifted based on the clock signal and each latch being arranged to keep said value a predetermined number of half clock cycles, where said value is shifted into a following latch delayed with half a clock cycle of the clock signal compared with a previous latch, and
an interpolating unit (34) arranged to interpolate a first ( Q̅1̅) and a second (Q6; Q4; Q8) intermediate signal, each provided through information stored in a latch (18, 28; 18, 24; 18, 72), for forming said first output signal.

11. Device according to claim 10, wherein the interpolating unit is connected to the first and (N+1)-th latch of said set for forming said first output signal, where N is the integer by which the clock signal frequency is divided.

12. Device according to claim 10, wherein the interpolating unit is arranged to combine the signal edges of the first and second intermediate signals, such that the first output signal has edges at points in time that are shifted from the edges of the clock signal.

13. Device according to claim 10, further comprising a signal edge copying unit (36) arranged to process a third (Q3; Q2; Q4) and fourth (Q4; Q3; Q5) intermediate signal provided through two other latches (22, 24; 20, 22; 24, 26) in order to provide a second output signal (O_I) having the same frequency as the first signal but being phase shifted from the first output signal.

14. Device according to claim 13, wherein the signal edge copying unit is arranged to obtain an edge of one type of the third intermediate signal and a following edge of an opposite type of the fourth intermediate signal and provide a level in-between that both the third and fourth intermediate signal have for the majority of the interval defined by said edges for the second output signal.

15. Device according to claim 14, wherein the signal edge copying unit is connected to the ((N+1)/2)-th and ((N+1)/2+1)-th latch in the set, where N is the integer by which the clock signal frequency is divided.
